(19) United States
(12) Patent Application Publication
(10) Pub. No.: US 2026/0239526 A1
(43) Pub. Date: Aug. 13, 2026

(54) COMPACT WIDEBAND PCB BANDPASS FILTER USING MUSHROOM-SHAPED RESONATORS

(71) Applicant: VIETTEL GROUP, Ha Noi City (VN)

(72) Inventors: THI VAN BUI, Ninh Binh Province (VN); DUC NHAT NGUYEN, Ha Noi City (VN); SI VINH HO, Nghe An Province (VN); DINH HAI TRUYEN HOANG, Ha Noi City (VN)

(73) Assignee: VIETTEL GROUP, Ha Noi City (VN)

(21) Appl. No.: 19/433,743

(22) Filed: Dec. 27, 2025

(30) Foreign Application Priority Data
Dec. 27, 2024 (VN) 1-2024-09793

(51) Int. Cl. H05K 1/02; H01P 1/20; H01Q 1/48; H05K 1/11

(52) U.S. Cl. CPC H05K 1/0243; H01P 1/20; H01Q 1/48; H05K 1/115; H05K 2201/1006

(57) ABSTRACT

A multilayer PCB bandpass filter employing mushroom-shaped resonator elements is disclosed. The architecture targets next-generation RF front ends, including 6G. It achieves a quality factor Q of about 400 and a passband of roughly 200 MHz. Low-loss dielectric layers and controlled inter-resonator coupling are used. Each resonator includes concentric disk plates and a solid vertical via to form a high-Q capacitive element. Top and bottom ground planes, together with edge plating, create a continuous metallic enclosure. This enclosure suppresses electromagnetic leakage and stabilizes the response. Inductive coupling windows between adjacent resonators set the bandwidth and maintain good impedance matching, yielding low return loss. The filter provides low insertion loss and a compact footprint. No post-fabrication tuning is required. The structure integrates readily into communication modules and radar front ends. Compared with conventional cavity filters, it reduces size, manufacturing complexity, and cost while preserving high selectivity and stable performance.

### TECHNICAL FIELD

The present disclosure relates to radio frequency (RF) bandpass filter, specifically to a multilayer PCB filter constructed from wideband mushroom-shaped resonator elements.

### BACKGROUND OF THE DISCLOSURE

In modern wireless transceiver systems such as those used in telecommunications and radar applications, frequency filters are essential components. They are responsible for removing unwanted emission noise from transmitters to prevent interference with nearby circuits or devices. In addition, the filters help suppress external interference that may couple into the receiver path. Future-generation wireless architectures, such as 6G systems, are expected to utilize an extended mid-band frequency range around 5-7 GHz to achieve a balance between coverage and capacity. In these dense deployment environments, RF bandpass filters are required to be compact, exhibit low in-band insertion loss, maintain stable bandwidth, and remain robust and suitable for mass production under varying environmental conditions.

Conventional bandpass filters used in 3G, 4G, and 5G telecommunication transceiver systems typically employ air-cavity resonator structures. While such filters offer advantages including high power-handling capability, excellent frequency selectivity, and high quality factor (Q), they also suffer from drawbacks such as large physical size, heavy weight, and high manufacturing cost. Compact planar filter solutions available on the market provide smaller form factors but exhibit higher insertion loss and greater sensitivity to manufacturing tolerances (e.g., via diameter, surface roughness). These conventional planar designs have not fully exploited the potential of multilayer dielectric stacking to enhance the quality factor (Q) and reduce losses.

This disclosure provides the design of a printed circuit board (PCB) bandpass filter employing mushroom-shaped resonator elements with low insertion loss. The operating frequency and characteristic of the fabricated filters are fixed after manufacturing and do not require post-tuning. Thanks to modern PCB fabrication technology, dimensional deviations between the fabricated filter and the simulated model are negligible. As a result, manual adjustment or fine-tuning steps typically required for conventional filters can be eliminated, significantly reducing production time and cost compared with traditional air-cavity or mechanically tuned filters.

The disclosure presents a PCB-based bandpass filter utilizing mushroom-shaped resonator elements with a simple structure and a high quality factor (Q) up to 400. The coupling bandwidth between two resonators units is approximately 500 MHz when operated independently, making its suitable for filters requiring wide bandwidth and low in-band insertion loss. To achieve these performance parameters, the capacitive element is formed on a solid multilayer printed circuit board, consisting of disk-shaped conductive plates and vertical via post arranged across multiple conductor layers.

### SUMMARY OF THE INVENTION

According to one representative embodiment, the filter includes:
1. A PCB structure consisting of four dielectric layers and five conductive layers, arranged from top to bottom. The top surface (first conductive layer) and the bottom surface (fifth conductive layer) are fully covered with 1-oz copper. These two layers function as the upper and lower ground planes, and together with edge plating, form a continuous conductive enclosure surrounding the resonator elements. The second and third conductive layers contain two concentric polygonal disks of equal diameter but different thickness, separated by a dielectric layer to create a planar capacitor.
2. The dielectric between the disks should have lower permittivity (εr) and lower loss tangent (tan δ) than adjacent layers. This ensures that electric charges move between the capacitor plates with minimum loss, improving the Q-factor and lowering in-band insertion loss.
3. A solid via post runs vertically from the center of the disk on the third layer to the bottom layer.
4. The complete filter can include two or more mushroom-shaped resonators, depending on the required filter slope, ripple and band rejection, while maintaining the same structural principle.
5. For the first and last resonators of the filter, a signal trace (placed on the fourth layer) connects the via post to the boundary of the resonator in the horizontal plane. These traces serve as the input and output feed lines of the filter. The trace width should be equal to or slightly larger than, but not exceeding 120% of the via diameter, to maintain optimal group delay.
6. Edge-loss reduction features are arranged along the four side surfaces of the continuous ground enclosure to suppress surface currents and parasitic edge effects, thereby stabilizing the resonant response. These features do not interrupt the electrical continuity of the plated sidewalls.

In one embodiment, each feature is formed as a semi-circular recess. In other variants, the feature may take the form of a chamfer or a short slot of equivalent dimensions. The diameter of each semi-circular recess is approximately λ/8 at the design frequency.

### BRIEF DESCRIPTION OF DRAWINGS

FIG. 1—View of a single mushroom-shaped resonator element on a multilayer printed circuit board structure.

FIG. 2—Cross-sectional view showing the layer stack of a mushroom-shaped resonator element.

FIG. 3—Simulated coupling coefficient model between a pair of mushroom resonator elements of the filter with the metallic enclosure omitted for clarity.

FIG. 4—inductive coupling bandwidth between a pair of mushroom resonator elements on a multilayer PCB.

FIG. 5—Model of the bandpass filter composed of mushroom-type resonator elements on a multilayer PCB structure.

FIG. 6—Bottom view of the bandpass filter illustrating the dimensions of the resonator elements and the inductive coupling windows.

FIG. 7—Transmission (S21) and reflection (S11) characteristics of the multilayer PCB bandpass filter consisting of three mushroom-shaped resonator elements.

FIG. 8—Effect of the coupling-window depth on the filter response (comparison between two design variants).

FIG. 9—Photograph of the completed bandpass filter prototype with three mushroom-shaped resonator elements.

### DETAILED DESCRIPTION

The filter described herein is composed of three mushroom-shaped resonator elements implemented on a multilayer printed circuit board (PCB). The multilayer PCB structure included four dielectric layers, five conductive layers, and one via post, arranged as follows: top surface (TOP), first conductive disk, second conductive disk, feed line, and bottom surface (BOTTOM). Referring to FIG. 5, the components of the filter can be functionally classified as follows:

### Mushroom-Shaped Resonator Element

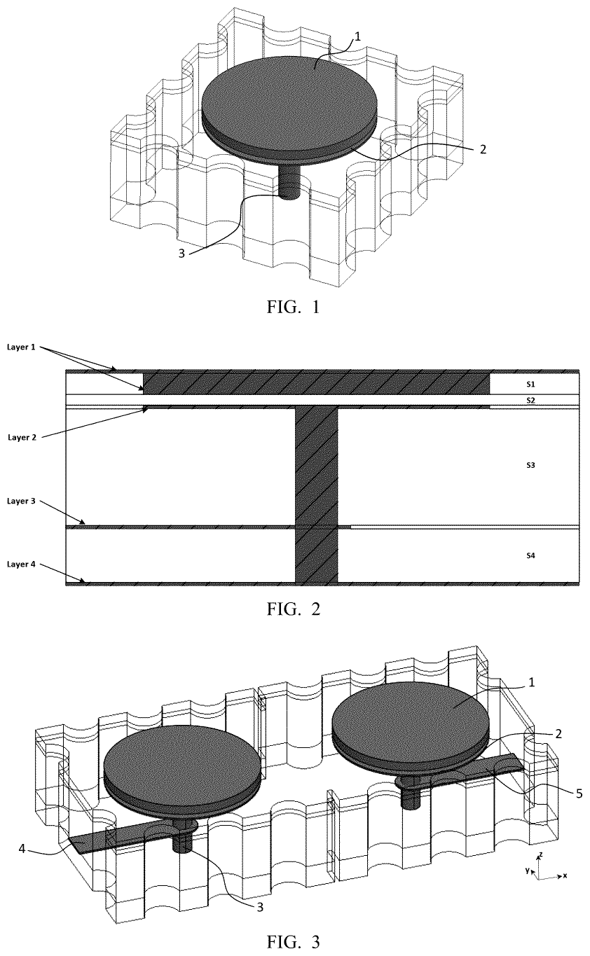

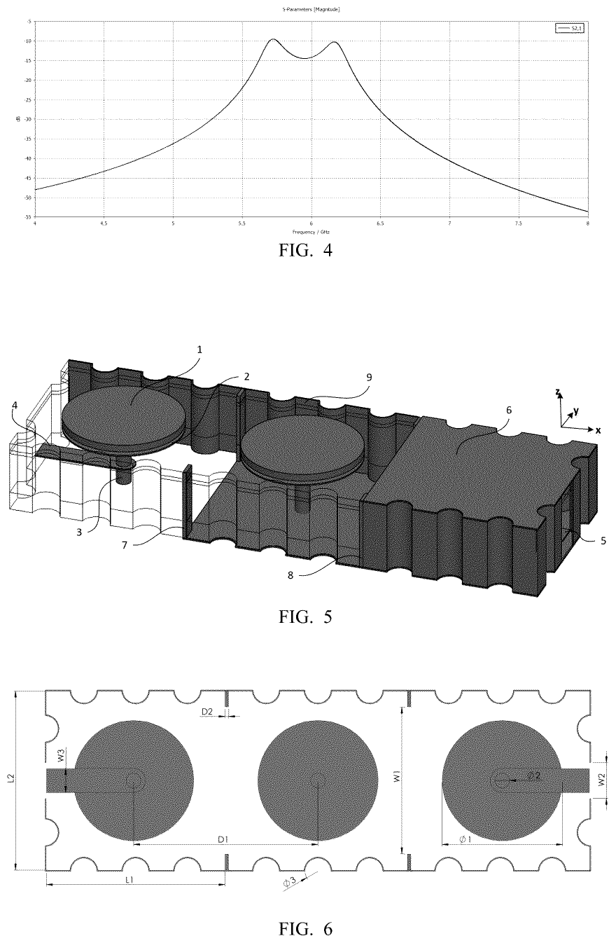

Each resonator consists of first conductive disk (1) and a second conductive disk (2) (see FIG. 1). The two resonator disks may be designed as circular or regular polygonal shapes with identical radius, positioned coaxially and parallel to each other, separated by a dielectric layer. This configuration functions as a planar capacitor, whose capacitance determines the operating frequency of the filter. The first conductive disk (1) is printed on the underside of the top layer, ensuring maximum electrical contact area. The second conductive disk (2) is coaxially aligned and mounted on a solid via post (3). The capacitance C of the basic capacitor structure can be expressed as:

$$C = \frac{ε {ε}_{0} S}{d}$$

In this equation, ε and ε₀ denote the dielectric constant of the insulating material between the two capacitor plates and that of free space, respectively. d represents the distance between the plates (or the thickness of the dielectric layer), and S is the plate area. From this relationship, it can be seen that the capacitance of the structure is independent of the plate material, but depends on the dielectric constant, plate area, and separation distance between the two plates.

In this design, the spacing d between the two disks (corresponding to the thickness of dielectric layer S2) is approximately 0.x mm and can be varied within a few tenths of a millimeter to fine-tune the resonant frequency. The two parallel disks are placed on different conductive layers to make efficient use of vertical space and to realize the desired filtering characteristics. However, the thicknesses of the two polygonal disks are intentionally different: the first conductive disk (1) is attached to Layer 1 (top layer), whereas the second conductive disk (2) is coaxially mounted on the copper via post (3) that connects to Layer 5 (bottom layer) of the resonator element (see FIG. 2).

### Connections

The filter includes two kinds of connections: signal connections and inter-resonator couplings. For signal connections, feed lines (4 and 5) are linked to the copper vias (3) of the end resonators, carrying the RF signal into and out of the filter (FIG. 3). Both ports are functionally identical, serving as input or output depending on signal direction.

The second type, the inter-resonator coupling, is implemented through inductive coupling windows.

In a three-resonator configuration, the first window (7) lies between the first and second resonators, and the second window (8) lies between the second and third. Each window is a slot cut into the sidewall conductor, reducing part of its width and height while preserving continuous electrical contact along the enclosure perimeter. The coupling coefficient k, and therefore the passband bandwidth, is determined by the window width (W1) and depth (D2) (FIG. 6). For a filter containing n mushroom-shaped resonators arranged in series, there are (n−1) coupling windows, with coupling values k₁ through kₙ₋₁ optimized to achieve the desired operating frequency and bandwidth.

### Physical Structure

The filter is constructed on a multilayer PCB consisting of several dielectric layers that provide electrical insulation between conducting structures. As shown in FIG. 2, the resonator components are distributed across four dielectric substrates: S1, S2, S3, and S4. The first disk conductor (1) is formed on layer S1, and the second disk conductor (2) is on layer S3, separated by layer S2, which has a lower permittivity and lower dielectric loss than the other layers. This specific stacking configuration helps improve the filter's electromagnetic performance, ensuring low loss and a stable Q-factor.

### Material and Enclosure Design

To reduce manufacturing cost and simplify fabrication, the dielectric layer S1, S3 and S4 use the same low cost PCB material commonly available in industry. The S2 layer should employ a low-loss dielectric with relative permittivity (er) between 2 and 3 and a loss tangent (tan δ) of about 0.001 or less—for example, Rogers 5880 (εr=2.2, tan δ=0.0009) as used in the simulation model. The outer enclosure incorporates edge-relief structures such as chamfered corners or shallow slots along the four sidewalls (FIG. 5). The radius of each recess (9) is optimized to achieve a high Q factor and lower in-band loss.

All side surfaces of the filter are edge-plated with a 15-25 μm copper layer, forming a closed resonant cavity, except at the two signal ports.

The resonant frequency of the mushroom-type capacitive element may be adjusted in the following order of priority:
Vary the radius of the two disk conductors, which directly affects the plate capacitance.
   Vary the spacing between the disks (the thickness if the interposed dielectric layer).
Select a different dielectric material for the interposed layer S2, characterized by its relative permittivity (εr) and loss tangent (tan δ).
   Vary the diameter of the vertical via post.

### DETAILED DESCRIPTION OF THE EMBODIMENTS

With reference to the example and illustration, the current disclosure will be further explanation in detail below, but the embodiment of the present disclosure is not limited thereto.

### Example

To demonstrate practical applicability, a multiplayer PCB bandpass filter comprising three mushroom-shaped resonator element was designed and electromagnetically simulated. The filter is suitable for transceiver systems operating in the 6G mid-band (5-7 GHz). The principal technical specifications are listed in the following Table I.

TABLE I
BANDPASS FILTER SPECIFICATIONS

| No. | Specifications | Requirements | |
|---|---|---|---|
| 1 | Operating Frequency | 5620-5820 | MHz |
| 2 | Bandwidth | 200 | MHz |
| 3 | Number of ports | 2 | Ports |
| 4 | Impedance | 50 | Ohm |
| 5 | In-band insertion loss | ≤0.8 | dB |
| 6 | Return Loss | ≥10 | dB |
| 7 | Out-band rejection | | |
| 7.1 | @5580 MHz | ≥40 | dB |
| 7.2 | @5860 MHz | ≥40 | dB |
| 8 | Maximum dimension | 18 × 6 × 2 | mm |

(L × W × H)

To meet the electrical targets and physical sixe constraints, the overall filter architecture is configured as shown in FIG. 9, with dimension parameters labeled in FIG. 6. The filters comprises three mushroom-shapes resonator elements, with representative dimensions summarized in Table II below.

TABLE II
BASIC DIMENSIONS OF THE
MUSHROOM-TYPE PCB FILTER

| No. | Symbols | Description | Value | |
|---|---|---|---|---|
| 1 | Ø1 | Disk diameter (layer 2/layer 3) | 1.63 | mm |
| 2 | Ø2 | Via post diameter | 0.4 | mm |
| 3 | Ø3 | Semi-circular edge recess | 0.7 | mm |
| | | diameter | | |
| 4 | L1, L2 | Resonator width | 4.93 | mm |
| 5 | D1 | Inter-resonators spacing | 4.98 | mm |
| 6 | D2 | Coupling window depth (Ox) | 0.1 | mm |
| 7 | W1 | Coupling window width (Oy) | 7.6 | mm |
| 8 | W2 | In/out port width | 0.97 | mm |
| 9 | W3 | Feed line width | 0.65 | mm |

FIG. 6 is a bottom view of the filter showing three resonator elements connected in series and separated by two inductive coupling windows. The window depth D2 is measured along the Ox axis and the width W1 along Oy. By resizing these apertures, the designer sets the inter-resonator coupling (k) to meet the desired bandwidth and return loss. Planar feed lines at two ends provide the input and output ports. In this example, S1, S3 and S4 are Rogers 3003 (εr=3, tan δ=0.001), and S2 is Rogers 5880 (εr=2.2, tan δ=0.0009). The S2 dielectric is preferably selected to have a lower permittivity and lower loss tangent than other layers

TABLE III
SIMULATION RESULT

| No. | Specifications | Requirement | | Simulation results | |
|---|---|---|---|---|---|
| 1 | Operating bandwidth | 5620-5820 | MHz | 5620-5820 | MHz |
| 2 | Bandwidth | 200 | MHz | 200 | MHz |
| 3 | Number of ports | 2 | | 2 | |
| 4 | Impedance | 50 | Ohm | 50 | Ohm |
| 5 | In-band insertion loss | ≤0.8 | dB | 0.5 | dB |
| 6 | Return Loss | ≥10 | dB | 11.3 | dB |
| 7 | Out-band rejection: | | | | |
| 7.1 | @5580 MHz | ≥40 | dB | 42 | dB |
| 7.2 | @5860 MHz | ≥40 | dB | 43 | dB |
| 8 | Maximum dimension | 18 × 6 × 2 | mm | 15 × 5 × 2 | mm |

(L × W × H)

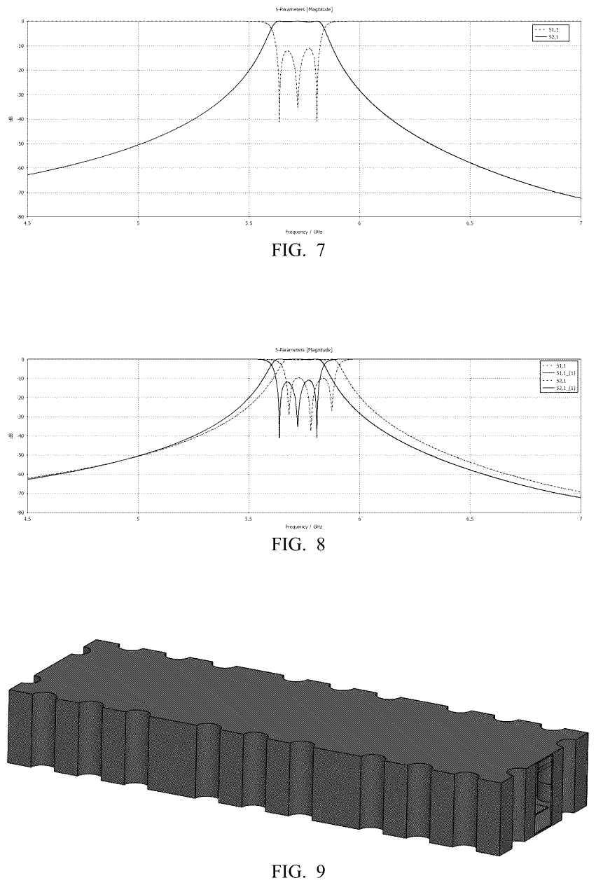

The frequency response of the filter is illustrated in FIG. 7 as the return loss (S11) and insertion loss (S21) parameters. Three resonant peaks appear within the passband, corresponding to the three resonator elements. Within the 200 MHz passband, S11 is better than 11 dB and insertion loss is less than 0.5 dB, confirming good matching and low loss. The filter thus meets the initial technical targets. Owing to its compact footprint, the design is suitable for the surface-mount (SMT) integration with RF front-end modules or antennas.

What is claimed is:

1. A radio-frequency bandpass filter comprising: a multilayer printed circuit board (PCB) including multiple dielectric layers and multiple conductive layers; at least two mushroom-shaped resonator elements connected in series, each resonator including two facing conductive disks disposed on different conductive layers and a solid via post electrically connecting at least one of the conductive disks to a ground layer; a continuous ground enclosure formed by an upper ground plane, a lower ground plane, and edge plating around the perimeter; and inductive coupling windows located between adjacent resonators, a dimensions of which are selected to set an inter-resonator coupling strength and thereby define a passband bandwidth.

2. The radio-frequency bandpass filter of claim 1, wherein an input and an output port each include a pad or planar feed trace connected to the via post of an end resonator and extending to a perimeter without electrical contact to the ground enclosure.

3. The radio-frequency bandpass filter of claim 1, wherein an interposed dielectric layer (S2) between the two facing conductive disks of each resonator has a relative permittivity εr of 2.1-3.4 and a loss tangent tan δ≤0.001.

4. The radio-frequency bandpass filter of claim 1, wherein a thickness of the S2 layer (disk spacing) is 0.1-0.5 mm.

5. The radio-frequency bandpass filter of claim 1, wherein a via-post diameter of each resonator is 0.2-0.6 mm.

6. The radio-frequency bandpass filter of claim 1, wherein a coupling window width (W1) is 6-9 mm and a window depth (D2) is 0.05-0.20 mm.

7. The radio-frequency bandpass filter of claim 1, wherein an edge plating has a thickness of 15-25 μm and is electrically continuous around the perimeter except at the two signal ports.

8. The radio-frequency bandpass filter of claim 1, wherein edge-loss reduction features are formed along sidewalls of the ground enclosure and are selected from semi-circular recesses, chamfers, or short slots, each having a characteristic radius/length of 0.3-0.8 mm and arranged with a pitch of 0.8-1.6 mm, while preserving edge-plating continuity.

9. The radio-frequency bandpass filter of claim 1, wherein a trace width of each input/output feed is equal to or greater than, and not exceeding 120% of, a via-post diameter to maintain an optimized group-delay behavior.

10. The radio-frequency bandpass filter of claim 1, wherein the conductive disks of each resonator are circular or regular polygonal with substantially equal projected area.

11. The radio-frequency bandpass filter of claim 1, wherein the radio-frequency bandpass filter comprises three mushroom-shaped resonators connected in series.

12. The radio-frequency bandpass filter of claim 1, wherein the radio-frequency bandpass filter comprises four mushroom-shaped resonators connected in series.

13. The radio-frequency bandpass filter of claim 1, configured to provide an input return loss |S11|≥10 dB across a nominal passband of about 200 MHz.

14. The radio-frequency bandpass filter of claim 13, wherein an in-band insertion loss is ≤0.8 dB.

15. The radio-frequency bandpass filter of claim 13, wherein an out-of-band attenuation is ≥40 dB at frequency offsets of approximately 40 MHz beyond a passband edge.

16. The radio-frequency bandpass filter of claim 1, wherein the multilayer PCB comprises four dielectric layers and five conductive layers, with top and bottom conductive layers fully copper-clad to act as the upper and lower ground planes.

17. The radio-frequency bandpass filter of claim 1, wherein the two conductive disks of each resonator are concentric and parallel, separated by the S2 dielectric layer, and the second disk is mounted on the solid via post.
